(19) United States
(12) Patent Application Publication
(10) Pub. No.: US 2008/0259758 A1
(43) Pub. Date: Oct. 23, 2008

(54) Partial Response Maximum Likelihood Decoding

(75) Inventor: Alexander Padiy, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/090,368

(22) PCT Filed: Oct. 11, 2006
(86) PCT No.: PCT/IB2006/053730

§ 371 Date: Apr. 16, 2008

(30) Foreign Application Priority Data
Oct. 19, 2005 (EP) 05109721.0

(51) Int. Cl. G11B 20/18; H03M 13/41

(52) U.S. Cl. 369/59.22; 714/794

(57) ABSTRACT

A partial response maximum likelihood decoder, such as a Viterbi decoder, implements a set of combined states where each combined state can represent at least two states from a plurality of complementary sets of states. For each data symbol and each combined state, a Viterbi processor (703) determines a path metric and a substate indication for each path to the combined state. A path selection processor (709) of the Viterbi processor (703) selects a selected path and a selected sub state indication for the path which corresponds to a highest likelihood path metric. The substate indication is an indication of which of the complementary set of states the combined state represents for the data symbol. The invention allows a substantial complexity reduction and/or reduced computational burden as the Viterbi algorithm can be applied to a reduced number of combined states.

### FIELD OF THE INVENTION

The invention relates to partial response maximum likelihood decoding and in particular, but not exclusively, to Viterbi decoding for optical storage disc reading systems.

### BACKGROUND OF THE INVENTION

Methods and techniques for detecting and correcting bit errors in data processing or distribution systems are widely known. For example, communication systems wherein data is communicated over an unreliable communication link typically employ forward error correction coding and decoding to reduce the amount of communication errors. As another example, optical disc reading systems tend to employ error decoding in order to reduce the amount of reading errors.

A particularly efficient technique for detecting correct bit values in the presence of bit errors is known as Partial Response Maximum Likelihood (PRML) bit detection. In particular, the Viterbi algorithm is commonly used for communication systems and data extraction from storage media, such as optical discs, in the presence of media and electronics noise.

Specifically, Viterbi based bit detection is frequently used in high-end modem optical disc systems in order to achieve reliable extraction of data stored on the optical disc. Furthermore, Viterbi bit detection is expected to play a major role for future generations of optical storage. In particular, the use of Viterbi detection allows an increment of the capacity of the Blu-ray™ Disc (BD) system from 25 GB to 35 GB per recording layer on a 12 cm disc.

However, the Viterbi algorithm is relatively complex and requires large amounts of processing power and computational resource. Indeed, the associated hardware cost is one of the factors that currently limit an even wider acceptance of the algorithm in optical disc storage systems. This issue becomes especially critical when fast parallel Viterbi configurations are employed in fast optical disc reading systems where a significant number of Viterbi detectors are used in parallel. In such systems, a number of Viterbi detectors must concurrently be made available in hardware (or in software in case of a Digital Signal Processor (DSP)-based implementation).

A number of different solutions have been proposed for reducing the hardware/software burden associated with the implementation of the Viterbi bit detector.

For example, U.S. patent application No. 6,580,766 discloses a reduced complexity PRML bit detector wherein certain states in the finite state machine defining the Viterbi trellis are merged in such a way that the overall detection performance remains essentially unchanged while the hardware cost is reduced.

Furthermore, Patent Cooperation Treaty patent application WO 01/10044 A discloses a specific low-complexity Viterbi decoder for channels with relatively low memory length employing a channel code with a Run Length Limited (RLL) code having a minimum run-length of three data symbols (i.e. following a data transition the minimum of consecutive identical data values is three, (corresponding to a constraint length of d=2)).

However, although these techniques may reduce complexity for some specific classes of data coding, the techniques cannot be generally applied to other coding systems. Specifically, only very specific Viterbi trellis structures can be used in the above mentioned algorithms. For example, the system disclosed in WO 01/10044 A requires a minimum run length of 3 (i.e. d=2 RLL codes) and cannot be applied to RLL codes having a run length of 2 (i.e. d=1 RLL codes).

Hence, an improved partial response maximum likelihood decoding system would be advantageous and in particular a system allowing for increased flexibility, reduced complexity, reduced computational resource demand, increased applicability and/or improved performance would be advantageous.

### SUMMARY OF THE INVENTION

Accordingly, the Invention seeks to preferably mitigate, alleviate or eliminate one or more of the above mentioned disadvantages singly or in any combination.

According to a first aspect of the invention there is provided a partial response maximum likelihood decoder implementing a set of combined states, each combined state being arranged to represent at least two from a plurality of complementary sets of states, the decoder comprising: path selection means for, for a plurality of data symbols, determining for each combined state a path metric and a substate indication for each path to the combined state and for selecting a selected path and selected substate indication corresponding to a highest likelihood path metric; wherein the substate indication is an indication of which of the complementary sets of states the combined state represents for the data symbol.

The invention may reduce the complexity of a partial response maximum likelihood decoder and/or may reduce the computational resource requirement. The invention may reduce hardware requirements and/or reduce cost for a partial response maximum likelihood decoder. As an increased complexity can be achieved for a given hardware and/or software limitation, improved decoding may be achieved.

By determining and tracking a selected substate indication for the combined states, state merging techniques can be applied to larger class of coding schemes including run length limited codes with a minimum run length of one or two data symbols.

The partial response maximum likelihood decoder may be a Viterbi decoder.

The path metric may be determined as a path metric of a precursor state plus a branch metric of the branch from the precursor state to the combined state. The highest likelihood path metric is the path metric of the path metrics determined for the combined state which is indicative of the highest likelihood of the corresponding path being the correct path. Thus, for systems using a path metric wherein an increasing value is indicative of an increasing probability of the path being correct, the highest likelihood path metric is the highest value path metric. Equivalently, for systems using a path metric wherein a decreasing value is indicative of an increasing probability of the path being correct, the highest likelihood path metric is the lowest value path metric.

In addition to combined states, the decoder may implement single states which do not represent a plurality of substates. In particular, a state trellis or state machine may be implemented comprising both combined and non-combined states.

According to an optional feature of the invention, the decoder further comprises means for storing the selected substate indication for each combined state and for at least some of the plurality of data symbols.

This may facilitate decoding and provide an efficient implementation.

According to an optional feature of the invention, the decoder further comprises trace back means for determining data symbol values in response to the stored selected substate indications for the plurality of data symbols.

This may facilitate decoding and provide an efficient implementation. In particular, the feature may allow efficient path decoding in a partial response maximum likelihood decoder using combined states.

According to an optional feature of the invention, the path selection means is arranged to determine a first branch metric for a first path in response to a substate indication of a precursor combined state from which the first path originates.

This may provide an improved partial response maximum likelihood decoder. The first branch metric may be determined in response to an expected reference signal for the branch where the expected reference signal depends on the substate of the precursor combined state.

According to an optional feature of the invention, the path selection means is arranged to determine a first substate indication for a first path in response to a substate indication of a precursor combined state from which the first path originates.

This may provide an improved partial response maximum likelihood decoder and may in particular allow an efficient and reliable means for determining the substate indication and thus which of the complementary sets of states the combined state is considered to represent for the current data symbol.

According to an optional feature of the invention, the first substate indication is uniquely determined by the substate indication of the precursor combined state.

The path selection means may be arranged to uniquely select the substate indication from the substate indication of the precursor combined state. The precursor combined state can specifically be the selected most likely precursor state for the current combined state. The substate indication of one combined state can be uniquely defined by the substate indication of the precursor combined state for a given structure of the state trellis or state machine implemented. Thus, there may be a one to one correspondence between the substate which is represented by the combined state and the substate which was represented by the precursor combined state for the selected path.

In some embodiments, the first substate indication is uniquely determined by a substate indication of the precursor non-combined state.

This may provide an improved partial response maximum likelihood decoder and may in particular allow an efficient and reliable means for determining the substate indication and thus which of the complementary sets of states the combined state is considered to represent for the current data symbol.

According to an optional feature of the invention, the data symbols are binary data symbols.

The invention may allow an improved partial response maximum likelihood decoder for binary data.

According to an optional feature of the invention, the complementary sets of states comprises a first set of states corresponding to a first data symbol value assumption and a second set of states corresponding to a complementary data symbol value.

The invention may allow an improved partial response maximum likelihood decoder for binary data. Complexity and/or computational resource requirements may be reduced by representing complementary states corresponding to opposite sign assumptions by a single combined state. Particularly advantageous performance may be achieved for binary data values with only two complementary sets of states and in particularly a reliable detection of which of the two set is represented by the combined states can be achieved.

According to an optional feature of the invention, the data symbols are encoded using a run length limited code having a minimum run length of one or more data symbols.

The invention may allow an improved partial response maximum likelihood decoder for run length limited coded data and may allow complexity and/or computational resource reduction for an increased class of codes.

According to an optional feature of the invention, the data symbols are encoded using a run length limited code having a minimum run length of one data symbol.

The invention may allow an improved partial response maximum likelihood decoder for run length limited coded data and may allow complexity and/or computational resource reduction for run length limited codes with a minimum run length of only one data symbol.

According to another aspect of the invention, there is provided an optical disc reading apparatus comprising a decoder as described above.

According to another aspect of the invention, there is provided a method of decoding for a partial response maximum likelihood decoder implementing a set of combined states, each combined state being arranged to represent at least two states from a plurality of complementary sets of states, the method comprising: for a plurality of data symbols, determining for each combined state a path metric and a substate indication for each path to the combined state; and selecting a selected path and selected substate indication having the best path metric; wherein the substate indication is an indication of which of the complementary set of states the combined state represents for the data symbol.

These and other aspects, features and advantages of the invention will be apparent from and elucidated with reference to the embodiment(s) described hereinafter.

### BRIEF DESCRIPTION OF THE DRAWINGS

Embodiments of the invention will be described, by way of example only, with reference to the drawings, in which

FIG. 1 is illustrates an example of an optical disc reader comprising some embodiments of the invention;

FIG. 2 illustrates an example of a state trellis for a Viterbi decoder;

FIG. 3 illustrates an example of a state machine for a Viterbi decoder;

FIG. 4 illustrates an example of a state machine for a Viterbi decoder;

FIG. 5 illustrates an example of a state machine for a Viterbi decoder;

FIG. 6 illustrates an example of a state machine for a Viterbi decoder;

FIG. 7 illustrates an example of a decoder in accordance with some embodiments of the invention;

FIG. 8 illustrates an example of a state machine for a Viterbi decoder;

FIG. 9 illustrates an example of a state machine for a Viterbi decoder;

FIG. 10 illustrates an example of a state machine for a Viterbi decoder; and

FIG. 11 illustrates an example of a state machine for a Viterbi decoder.

### DETAILED DESCRIPTION OF SOME EMBODIMENTS OF THE INVENTION

The following description focuses on embodiments of the invention applicable to optical disc reading system using a Run Length Limited (RLL) code. However, it will be appreciated that the invention is not limited to this application but may be applied to many other decoding systems including for example decoders for communication systems.

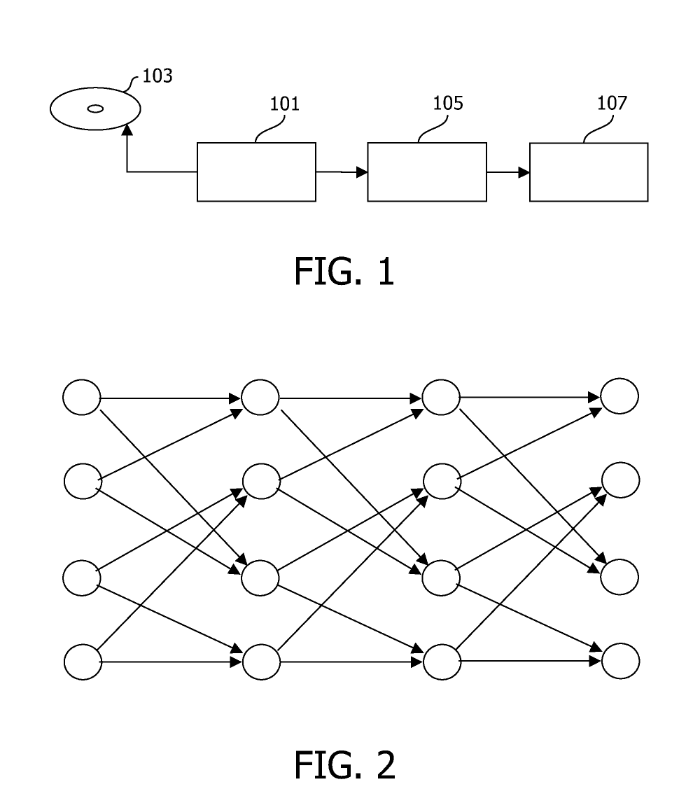

FIG. 1 illustrates an example of an optical disc reader comprising some embodiments of the invention.

In the example, an optical disc data reader 101 reads data from an optical disc 103. The data stored on the optical disc 101 is RLL coded. The data samples read from the optical disc are fed from the optical disc data reader 101 to a Viterbi bit detector 105. The Viterbi bit detector 105 uses at the Viterbi algorithm to determine the data values which are read from the optical disc 103. The detected data is fed to a data interface 107 which interfaces to external equipment. For example the data interface 107 may provide an interface to a personal computer.

As will be well known to the person skilled in the art, a partial response maximum likelihood decoder, such as a Viterbi decoder, generally decodes data using a state machine. For each new data sample, the possible state transitions and penalty values associated with these transitions are evaluated and used to select a surviving path for each possible state.

As a specific example, FIG. 2 illustrates a four state trellis diagram for a Viterbi decoder. In the example, each state has two possible precursor states and thus two paths entering the each state (corresponding to binary data and a two data value memory). For each state, a path metric is evaluated for both paths entering the state. The path having the best path metric (i.e. indicating the highest probability of being the correct path) is selected and the other path is discarded. Thus, for each state, only one surviving path (the path most likely to be correct) is selected.

The path metric is determined as the path metric of the precursor state plus a branch metric for the state transition from the previous state to the current state. This branch metric is typically calculated as a distance measure between the received sample and an expected sample for that transition. Thus, in such embodiments, the path metric may be seen as a penalty value for the path and the surviving path of each state is the path that has the lowest path metric.

Thus, for a given data sample, the Viterbi detector may not know exactly which of the possible state is the correct state. However, for each state, the most likely path is known and thus the most likely received bit sequence is known. In some cases, incoming data may be encoded such that a data sequence is included which is known to end in a specific state. In this case, the correct state is known and the most likely bit sequence can be determined by back tracking through the trellis along the selected path. Furthermore, it is a feature of Viterbi decoding that the paths of the different states tend to merge to the same path for sufficient delays and accordingly decoded bits may be generated continuously without relying on explicit knowledge of the correct state.

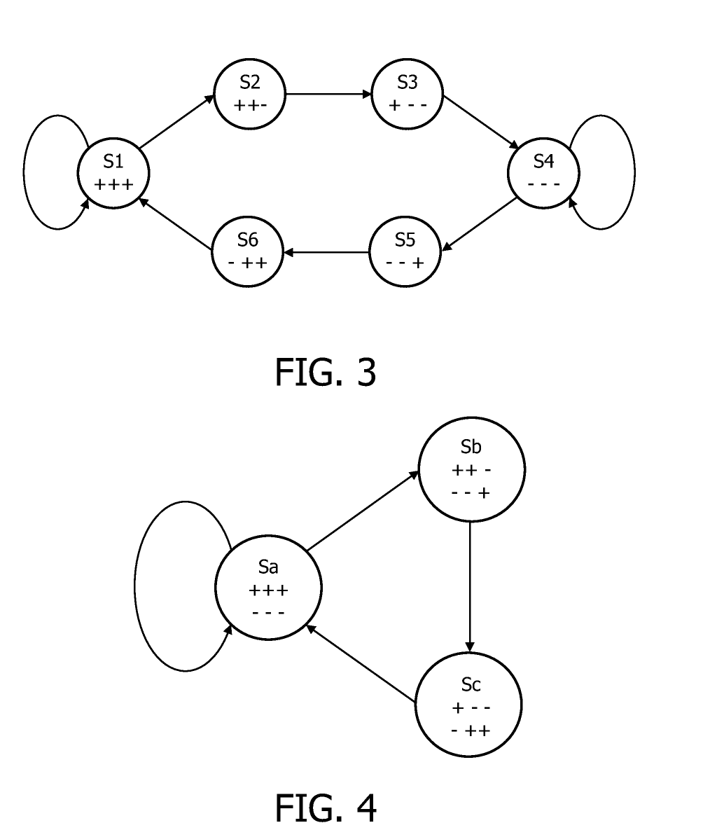

Patent Cooperation Treaty patent application WO 01/10044 A is concerned with Viterbi bit detection for a system having a three bit memory and using an RLL code with d=2 (i.e. with a minimum run length of three bits). The corresponding Viterbi states and transitions are illustrated in FIG. 3. In FIG. 3, the trellis states are shown as a state machine (i.e. without reflecting the time domain).

In the example, only six states are required as two of the states are not possible due to the d=2 RLL code. Specifically, the states +-+and -+- (corresponding to the data sequences 101 and 010 (or vice versa)) cannot occur. Furthermore, as can be seen the RLL coding significantly limits the possible state transitions.

In such a Viterbi detector, path metrics can be updated in the forward path according to the following rule:

$${PM}_{m}^{( k )} = {min}_{i} \{ {PM}_{{m}_{i} \to m}^{( k )} \} , \\ {PM}_{{m}_{i} \to m}^{( k )} = {PM}_{{m}_{i}}^{( k - 1 )} + {BM}_{{m}_{i} \to m}^{( k )}$$

where the branch metrics BMₘ_{ᵢ}_{→m}^{(k)} can be determined as an absolute value of the difference between the actual waveform value and the expected one:

BMₘ_{→m}^{(k)}=|Zₖ−Tₘ_{ᵢ}_{→m}|

although other distance measures can be used as well, for example a certain power of the absolute value of the difference.

In the equations, PMₘ^{(k)} denotes the path metric for the trellis state m at moment k in time, BMₘ_{ᵢ}_{→m}^{(k)} denotes the branch metric corresponding to the transition from state mᵢ at moment k−1 to state mat moment k, mᵢ denotes the predecessor states for state m, PMₘ_{ᵢ}_{→m}^{(k)} denotes the path metric of a candidate path arriving to state m via state mᵢ.

The branch metrics are computed as a distance measure of the difference between the actual received signal sample Zₖ and the so-called reference levels rₘ_{ᵢ}_{→m}, which correspond to the expected signal samples for the transitions from mᵢ to m (the reference levels are assumed to match the actual channel at hand).

It is implicitly assumed in the above procedure that the expected signal samples for the transitions from mᵢ to m (the reference levels) are uniquely defined by the source state mᵢ and the target state m.

In the system of WO 01/10044 A, a reduction in the computational demand is achieved by merging some of the Viterbi states into combined states. Specifically, it is suggested to fold the state diagram of FIG. 3 into the state diagram of FIG. 2. Thus, as can be seen, the states are divided into two different sets of complementary states corresponding to the sign inverted states, and a single combined state is used to represent both a state from the first set and a state from the second set.

In the specific example, state Sa can thus represent both states S1 and S4 corresponding to both the bit sequence +++ and −−−. Likewise, combined state Sb can represent both states S2 and S5 and combined state Sc can represent both states S3 and S6. Such a combination of states is generally feasible because, although the transitions of the RLL code may be difficult to detect and therefore require an extensive Viterbi detection approach, a long run length makes it relatively easy to determine the sign of the current sequence. For example, for a long run of binary data (say 50-100 consecutive data symbols), it is easy to reliably determine if the decoder is in state S1 or S4 and thus whether the combined states should represent the set corresponding to S1 or the set corresponding to S4.

The combination of states may result in a substantial reduction of computational resource as effectively only half of the states need to be evaluated for a given data value. Thus, in the example, an improvement of almost a factor of two can be achieved.

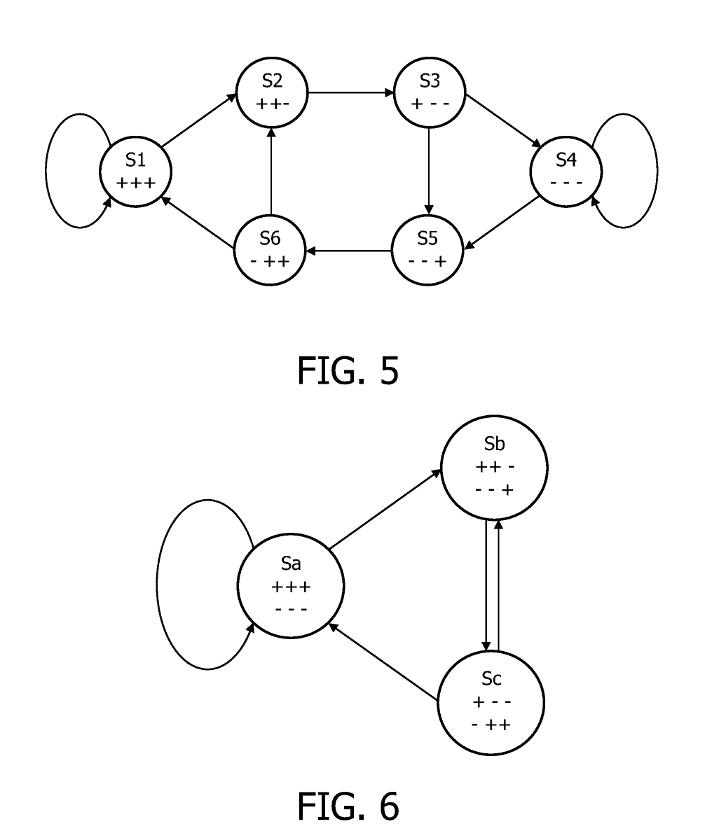

However, although the system of WO 01/10044 A allows for an efficient algorithm, the system is specifically aimed at systems with low channel memory and a minimal run length of three. The system is developed to modify the path metrics to reflect the limited freedom of movement between the different combined states. Specifically, the system use modified path metrics which reflect that the path from one run-length state (S1 or S4) is always through a specific sequence of intermediate states. E.g. for the example of FIG. 3 and 4, the path metrics reflect that the sequence from state S1 to S4 (or from S4 to S1) will always lead to the combined state sequence Sa-Sb-Sc-Sa. Accordingly, the path metrics are modified to reflect the possibility of the combined states representing one of two different sets of Viterbi states.

Unfortunately, the system of WO 01/10044 A cannot be applied to systems using lower minimum run lengths. For example, for a channel memory of three and a minimum run length of two data symbols (d=1), it is not possible to merely modify the path metrics or to assume that there is only one possible sequence between the full run length states (S1 and S4).

Specifically, for a system with a memory length of three and a minimum run length of two data symbols (d=1), the Viterbi state machine may be represented by the state diagram of FIG. 5. Using the same principles as for the system of WO 01/10044 A, this state diagram can be folded into the combined state diagram of FIG. 6. As illustrated in FIG. 6, this state diagram comprises transitions in both directions and it is not sufficient to merely consider the run length states S1 and S4 corresponding to Sa.

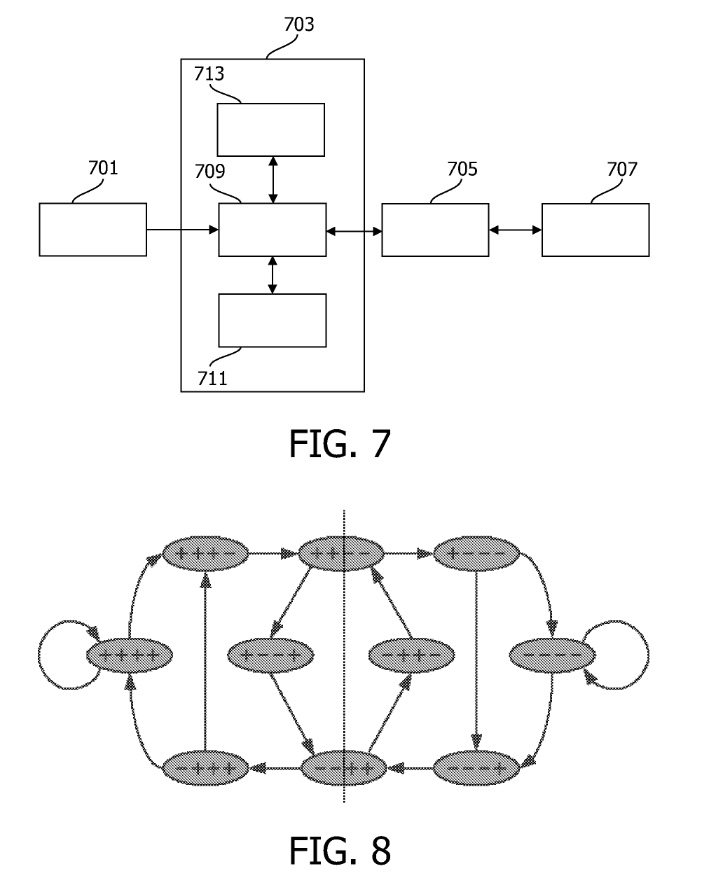

FIG. 7 illustrates a decoder in accordance with some embodiments of the current invention.

The decoder of FIG. 7 is arranged to overcome some of the shortcomings of the system of WO 01/10044 A. In particular, the decoder of FIG. 7 allows combined states to be used for Viterbi decoding of a large variety of encoding systems including systems which use a minimum run length of one or two data symbols (d=0 or d=1, correspondingly).

In particular, the decoder continuously determines the substate for each of the combined states for each data symbol. Thus, when a new data symbol is evaluated, the path metric for each path entering a combined state is determined. The path having the lowest path metric (in the example where the path metric is calculated as a penalty value) is selected and the substate of the combined state which corresponds to this path is determined. This substate indication is then stored for the state together with the path metric. Thus, the decoder of FIG. 7 continually keeps track of which substate is represented by the combined state for each combined state. During trace back, the stored substate indications are furthermore used to determine the correct data values.

In some situations it may occur that none of the substates for a given combined state is compatible with the substate indication of the preceding state, and in this case an infinite path metric can be associated with this transition. For example: some of the states of the Viterbi states can be the original non-merged states (i.e. not be combined states) and will therefore keep having their own sign, while some of their preceding states are combined states with both options for the sign.

By continually keeping track of the appropriate substate represented by each combined state (rather than just the full run-length states), it is possible to apply the concept of state merging to any finite state machine. In particular, it allows a combined state diagram to be used for a Viterbi detection of a RLL code with a minimum run length of two (d=1) in a system having a memory length of three data symbols.

The algorithm used by the detector of FIG. 7 is based on the observation that e.g. for the considered class of binary optical storage channels, the Viterbi detector is able to easily distinguish any of the trellis states from their mirrored (complementary) counterparts. Accordingly, if the path leading to a certain state is considered by the Viterbi detector to be highly probable, then the path leading to the mirrored (sign-flipped) counterpart of the considered state has a low probability. This observation allows the complementary states to be combined thereby effectively halving the number of states that must be considered. The selection of the substate indication, which indicates which of the substates (trellis states) are represented by the combined state, is determined dynamically during run-time and is based on tracking not only the path metrics in the Viterbi forward path but also the substate indication of previous states and in particular is based on the substate indication of the precursor state for the selected path.

Furthermore, the detection of the appropriate substates is highly reliable. Specifically, any extended run of identical data values will strongly bias the decoder to the correct substate assumption as the path metrics for the wrong assumption will increase very quickly. Thus, the error rate performance degradation associated with the complexity reduction is negligible in most applications.

In the example of FIG. 7, a state machine or trellis is implemented using only combined states which represent a plurality of substates. However, it will be appreciated that in other embodiments, a decoder may comprise one or more combined states together with one or more non-combined states. Thus, a state machine or trellis wherein only some of the original states are combined into a single state representation whereas other original states are maintained as individual single states can be used.

The decoder comprises a bit receiver 701 which receives the data samples from the optical disc data reader 101. The bit receiver 701 is coupled to a Viterbi processor 703. The Viterbi processor 703 is coupled to a data storage 705 wherein the determined information for the Viterbi trellis is stored. Specifically, the Viterbi processor 703 stores the accumulated path metric and substate indication for each of the combined states and for each of the data symbols in the data storage 705. The data storage 705 is furthermore coupled to a trace back processor 707 which is arranged to trace back through the combined substate trellis along the selected path to thereby generate the data bits of the selected path. The trace back processor 707 then feeds the decoded data to the data interface 107.

The Viterbi processor comprises a path selection processor 709 which for each combined state and for each data symbol selects a surviving path. The path selection processor 709 is coupled to a path metric processor 711 which is arranged to determine a path metric for the paths entering a given state. In addition, the path selection processor 709 is coupled to a substate processor 713 which determines the appropriate substate indication for a given state. Thus, the substate processor 713 determines which of the complementary sets the current combined state represents for the specific data sample.

In particular, when a new data sample is received from the receiver 701, the Viterbi processor 703 proceeds to evaluate all combined states. For each combined state, all paths entering the combined state are evaluated. For each path, the path selection processor 709 retrieves the path metric of the precursor state from the data storage 705 and passes this to the path metric processor 711. The path metric processor 711 then calculates a branch metric for the transition from the precursor combined state to the current combined state The branch metric generally also depends on the precursor substate indication as the reference level corresponding to the expected data value of the transition depends on this and adds this value to the retrieved path metric to generate a path metric for the current path. When the path selection processor 709 has obtained path metrics for all paths entering the combined state, it proceeds to select the path which has the lowest path metric as this is the path with the highest likelihood of being the correct path entering this combined state.

When the path selection processor 709 has selected the surviving path for the combined state, it proceeds to retrieve the substate indication of the precursor combined state for this path from the data storage 705. This substate indication is passed to the substate processor 713 which proceeds to determine the substate indication for the current combined state.

In many cases, the substate indication for the current combined state is uniquely defined by the substate indication of the precursor state and the specific transition. Thus, a set of rules may be predetermined which define how the substate indication of one combined state follows from the substate indication of the precursor state.

For example, for the state diagram of FIG. 6, if the precursor state is state Sa with the substate indication corresponding to the first set (say state S1, +++) and the transition is to state Sb, then the substate indication for this combined state will also be for the first set (state S2, ++−). As another example, if the precursor state is state Sc with the substate indication corresponding to the first set (say state S3, +−−) and the transition is to state Sb, then the combined substate indication for state Sb will be for the second set (state S5, −−+). The same principles can be applied to all the state transitions and the resulting rules can be implemented in the substate processor 713 allowing it to easily and uniquely determine the substate indication for the current combined state.

Thus, for the specific class of finite state machines, the substate of the precursor combined state mᵢ uniquely determines the sign of the target combined-state m since the transition from mᵢ to m is impossible if the substate indications do not match properly. The opposite is also true; the sign of the target combined state m determines uniquely the sign of the precursor combined state mᵢ.In other words, the finite state machine diagram uniquely defines the mapping from the substate indication of state mᵢ to the substate indication of state m, and back from the substate indication state m to the substate indication of state mᵢ.

The path selection processor 709 then proceeds to store the determined substate indication and path metric for the current combined state in the data storage 705. It then proceeds to the next combined state for the current data symbol, until all combined states have been evaluated. It subsequently proceeds to process the next data symbol in the same way.

The determination of the branch metric by the path metric processor 711 can be based on a distance measure relative to an expected value similarly to conventional Viterbi decoders. However, in the decoder of FIG. 7, the branch metric for a given path is determined in response to the substate indication of the precursor combined state for that path. Specifically, the path selection processor 709 retrieves the substate indication for the precursor path from the data storage 705 and feeds it to the path metric processor 711. The path metric processor 711 then uses this to determine the expected value, referred to as the reference level.

Specifically, the path metrics for the combined states can be determined as:

$${PM}_{m}^{( k )} = {min}_{i} \{ {PM}_{{m}_{i} \to m}^{( k )} \} , \\ {PM}_{{m}_{i} \to m}^{( k )} = {PM}_{{m}_{i}}^{( k - 1 )} + {BM}_{{m}_{i} \to m}^{( k )}$$

where the branch metrics BMₘ_{ᵢ}_{→m}^{(k)} is computed as

BMₘ_{ᵢ}_{→m}^{(k)}=∥zₖ−rₘ_{ᵢ}_{→m}^{s(m}^{ᵢ}^{)∥}

where ∥·∥ defines a distance measure, s(mᵢ) denotes the substate indication of the source super-state mᵢ, rₘ_{ᵢ}_{→m}^{s(m}^{ᵢ}⁾ is the expected data sample value for the transition and Zk is the data sample. If the preceding state indication is incompatible with the substates of the current state, the branch metric can be set to infinity thereby ensuring that the path transition will be discarded. Typically, the absolute value of the difference can be used for defining the distance measure due to implementation complexity considerations. The expected signal samples rₘ_{_{i→m}}^{s(m}^{ᵢ}⁾ for the transitions from mi to m (the reference levels) are uniquely defined by the precursor combined state mi and the target combined state m and the substate indication s(mᵢ) of the source super-state mᵢ.

The trace back processor 707 performs a trace back through the surviving path(s) using the stored substate indications for each combined state. Specifically, the substate indication of the combined states must not only be used during the forward path in the Viterbi trellis build-up as explained above, but also during the trace back procedure in order to ensure a unique mapping from the path through the trellis into the bit decision stream. Namely, bit decisions corresponding to the proper substate indications of the combined states should be used. The substate indication tracking of the predecessor states along the trace back path can be easily done similarly to the approach used for the forward path. Starting from the known substate indication of the combined state at moment k, the substate indication of the predecessor combined state mi is given by the fixed mapping from the substate indication of state m to the substate indication of state mᵢ, as set by the finite state machine diagram.

It will be appreciated that although the previous description has focused on binary data symbols, the principles are equally applicable to non-binary data symbols.

Furthermore, it will be appreciated that although the previous description has focused on combination of two Viterbi states into a single combined state, other groupings may be used in other embodiments. Specifically, in other embodiments, other clustering sizes may be used.

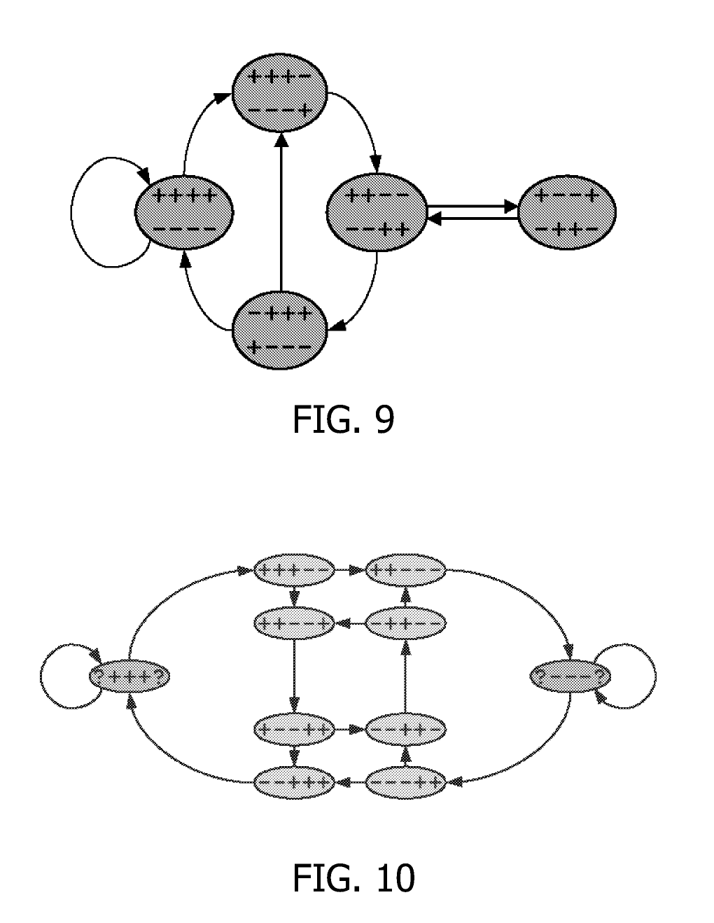

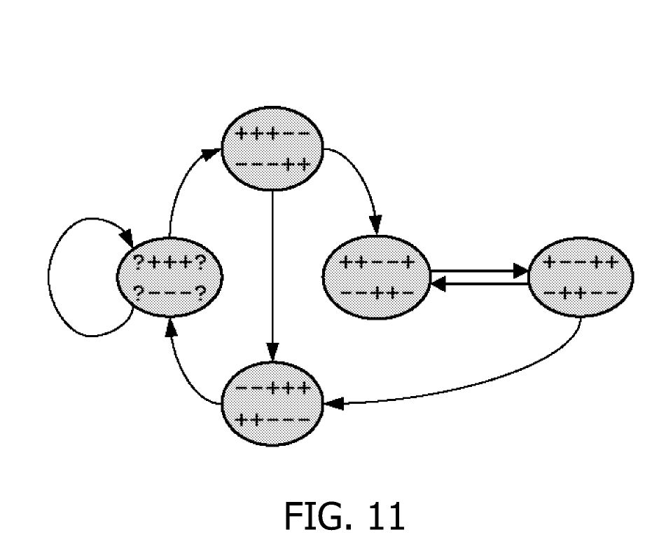

FIGS. 8 to 11 illustrate other examples of the combination of states being applied to other state machines. In particular, FIG. 8 illustrates a 4-tap state machine with d=1 which can be merged into the reduced state machine of FIG. 9. FIG. 10 illustrates a 5-tap state machine with d=1 which can be merged into the reduced state machine of FIG. 11.

It will be appreciated that the above description for clarity has described embodiments of the invention with reference to different functional units and processors. However, it will be apparent that any suitable distribution of functionality between different functional units or processors may be used without detracting from the invention. For example, functionality illustrated to be performed by separate processors or controllers may be performed by the same processor or controllers. Hence, references to specific functional units are only to be seen as references to suitable means for providing the described functionality rather than indicative of a strict logical or physical structure or organization.

The invention can be implemented in any suitable form including hardware, software, firmware or any combination of these. The invention may optionally be implemented at least partly as computer software running on one or more data processors and/or digital signal processors. The elements and components of an embodiment of the invention may be physically, functionally and logically implemented in any suitable way. Indeed the functionality may be implemented in a single unit, in a plurality of units or as part of other functional units. As such, the invention may be implemented in a single unit or may be physically and functionally distributed between different units and processors.

Although the present invention has been described in connection with some embodiments, it is not intended to be limited to the specific form set forth herein. Rather, the scope of the present invention is limited only by the accompanying claims. Additionally, although a feature may appear to be described in connection with particular embodiments, one skilled in the art would recognize that various features of the described embodiments may be combined in accordance with the invention. In the claims, the term comprising does not exclude the presence of other elements or steps.

Furthermore, although individually listed, a plurality of means, elements or method steps may be implemented by e.g. a single unit or processor. Additionally, although individual features may be included in different claims, these may possibly be advantageously combined, and the inclusion in different claims does not imply that a combination of features is not feasible and/or advantageous. Also the inclusion of a feature in one category of claims does not imply a limitation to this category but rather indicates that the feature is equally applicable to other claim categories as appropriate. Furthermore, the order of features in the claims do not imply any specific order in which the features must be worked and in particular the order of individual steps in a method claim does not imply that the steps must be performed in this order. Rather, the steps may be performed in any suitable order. In addition, singular references do not exclude a plurality. Thus references to “a”, “an”, “first”, “second” etc do not preclude a plurality. Reference signs in the claims are provided merely as a clarifying example shall not be construed as limiting the scope of the claims in any way.

1. A partial response maximum likelihood decoder implementing a set of combined states, each combined state being arranged to represent at least two states from a plurality of complementary sets of states , the decoder comprising:
path selection means (703) for, for a plurality of data symbols, determining for each combined state a path metric and a substate indication for each path to the combined state and for selecting a selected path and selected substate indication corresponding to a highest likelihood path metric; wherein the substate indication is an indication of which of the complementary set of states the combined state represents for the data symbol.

2. The decoder of claim 1 further comprising means (705) for storing the selected substate indication for each combined state and for at least some of the plurality of data symbols.

3. The decoder of claim 2 further comprising trace back means (707) for determining data symbol values in response to the stored selected substate indications for the plurality of data symbols.

4. The decoder of claim 1 wherein the path selection means (703) is arranged to determine a first branch metric for a first path in response to a substate indication of a precursor combined state from which the first path originates.

5. The decoder of claim 1 wherein the path selection means (703) is arranged to determine a first substate indication for a first path in response to a substate indication of a precursor combined state from which the first path originates.

6. The decoder of claim 5 wherein the first substate indication is uniquely determined by the substate indication of the precursor combined state.

7. The decoder of claim 1 wherein the data symbols are binary data symbols.

8. The decoder of claim 7 wherein the complementary sets of states comprises a first set of states corresponding to a first data symbol value assumption and a second set of states corresponding to a complementary data symbol value.

9. The decoder of claim 1 wherein the data symbols are encoded using a run length limited code having a minimum run length of one or more data symbols.

10. The decoder of claim 9 wherein the data symbols are encoded using a run length limited code having a minimum run length of one data symbol.

11. An optical disc reading apparatus comprising a decoder in accordance with claim 1.

12. A method of decoding for a partial response maximum likelihood decoder implementing a set of combined states, each combined state being arranged to represent at least two states from a plurality of complementary sets of states, the method comprising:
for a plurality of data symbols, determining for each combined state a path metric and a substate indication for each path to the combined state; and
selecting a selected path and selected substate indication having the best path metric; wherein the substate indication is an indication of which of the complementary set of states the combined state represents for the data symbol.
